(19) United States
(12) Patent Application Publication
(10) Pub. No.: US 2012/0018758 A1
(43) Pub. Date: Jan. 26, 2012

(54) OPTOELECTRONIC DEVICES WITH EMBEDDED VOID STRUCTURES

(75) Inventors: Elison de Nazareth Matioli, Goleta, CA (US); Claude C. A. Weisbuch, Paris (FR); James S. Speck, Goleta, CA (US); Evelyn L. Hu, Cambridge, MA (US)

(73) Assignee: THE REGENTS OF THE UNIVERSITY OF CALIFORNIA, Oakland, CA (US)

(21) Appl. No.: 13/189,778

(22) Filed: Jul. 25, 2011

Related U.S. Application Data
(60) Provisional application No. 61/367,239, filed on Jul. 23, 2010.

(51) Int. Cl. H01L 33/10; H01L 31/18; H01L 31/0232

(52) U.S. Cl. 257/98; 257/432; 438/31; 438/69; 257/E33.067; 257/E31.127

(57) ABSTRACT

An optoelectronic structure, and method of fabricating same, comprised of semiconductors having growth-embedded void-gap gratings or photonic crystals in one or two dimensions, which are optimized to yield high interaction of the guided light and the photonic crystals and planar epitaxial growth. Such structure can be applied to increase light extraction efficiency in LEDs, increase modal confinement in lasers or increase light absorption in solar cells. The optimal dimensions of the growth-embedded void-gap gratings or photonic crystals are calculated by numerical simulation using scattering matrix formalism. The growth-embedded void-gap gratings are applicable to any semiconductor device, as well as optoelectronic devices, such as light-emitting diodes, laser diodes and solar cells.

### CROSS-REFERENCE TO RELATED APPLICATIONS

This application claims priority under 35 U.S.C. §119(e) to co-pending and commonly-assigned U.S. Provisional Patent Application Ser. No. 61/367,239, filed on Jul. 23, 2010, by Elison de Nazareth Matioli, Claude C. A. Weisbuch, James S. Speck, and Evelyn L. Hu, and entitled “OPTOELECTRONIC DEVICES WITH EMBEDDED VOID STRUCTURES,” attorney's docket number 30794.385-US-P1 (2009-493-1), which application is incorporated by reference herein.

This application is related to co-pending and commonly-assigned:

U.S. Utility application Ser. No. 12/793,862, filed Jun. 4, 2010, by Claude C. A. Weisbuch, Aurelien J. F. David, James S. Speck, and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-C2 (2005-145-3), which application is a continuation of:

U.S. Utility application Ser. No. 11/923,414, filed Oct. 24, 2007, by Claude C. A. Weisbuch, Aurelien J. F. David, James S. Speck, and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-C1 (2005-145-2), now U.S. Pat. No. 7,755,096, issued Jul. 13, 2010, which application is a continuation of:

U.S. Utility application Ser. No. 11/067,910, filed Feb. 28, 2005, by Claude C. A. Weisbuch, Aurelien J. F. David, James S. Speck, and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1), now U.S. Pat. No. 7,291,864, issued Nov. 6, 2007,

all of which applications are incorporated by reference herein.

### STATEMENT REGARDING FEDERALLY SPONSORED RESEARCH AND DEVELOPMENT

This invention was made with Government support under Grant No. DE-FC26-06NT42857 awarded by the Department of Energy. The Government has certain rights in this invention.

### BACKGROUND OF THE INVENTION

1. Field of the Invention

The invention is related to the field of optoelectronic devices such as light emitting diodes (LEDs), laser diodes (LDs), and solar cells.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The growth of embedded structures was initially developed for defect reduction, such as threading dislocations, in semiconductors grown by heteroepitaxy. The property of selective growth of nitride semiconductors over dielectric masks by metalorganic chemical vapor deposition (MOCVD) and hydride vapor phase epitaxy (HVPE) made possible the development of lateral epitaxial overgrowth (LEO), which can greatly reduce the density of threading dislocations [1-6] in nitride semiconductors.

One common LEO technique uses a set of dielectric stripes periodically spaced to block threading dislocations in these regions during the semiconductor overgrowth, as shown in FIG. 1(a), which illustrates a substrate 100, semiconductor layer 102, dielectric stripes 104 and openings for overgrowth 106. After the lateral overgrowth, the dielectric stripes 104 are embedded inside the structure, as depicted in FIG. 1(b).

Embedded periodic structures within optoelectronic devices yield a periodic modulation of the index of refraction within the device, which serves as a diffracting medium that can be used to control the propagation of electromagnetic modes. For example, the light extraction efficiency in LEDs can be improved by surface gratings[7,8], and dielectric gratings can be used to create standing-wave lasing modes in distributed feedback (DFB) lasers [9,10], wherein the gratings comprise photonic crystals (PhC). Additionally, the photonic band gap properties of gratings can be applied to mirrors, as in distributed Bragg reflectors (DBRs), or for waveguides in integrated optoelectronic circuits.

Gratings are effective either on the surface or embedded in the semiconductor slab. The advantage of the latter is the much higher overlap between the electromagnetic guided modes and the grating, which enhances considerably their interaction.

The fundamental difference between the epitaxial growth of optoelectronic device gratings and LEO lies in the grating periodicity. While the spacing between the dielectric stripes in LEO is on the order of a few microns, optoelectronic devices may require the periodicity of the grating to be of the order of the wavelength of the light generated by this device. For nitride-based optoelectronic devices, the grating periodicity is typically on the order of few hundreds of nanometers, e.g., an order of magnitude smaller than the usual LEO dimensions. Another difference is that LEO relies on striped structures, whereas the growth and devices that are described herein most often require two-dimensional structures.

The semiconductor regrowth over the grating occurs on the grating openings, as shown in FIG. 1(a). Therefore, a reduction on the periodicity of the grating results in a reduction on the area available for overgrowth, which makes the fabrication of embedded gratings for optoelectronic devices much more difficult and more sensitive to inhomogeneities in the dielectric stripes, as well as to the remaining dielectric material inside or close to the opening edges of the stripes.

GaN-based DFBs [11] and LEDs [12] with an embedded periodic set of Si₃N₄ and SiO₂ stripes have already been demonstrated, wherein the stripes are also known as one dimensional photonic crystals (1D-PhCs). In 1D-PhC LEDs, the diffraction of guided modes occurs only for light propagating in the direction perpendicular to the stripes, which can be used for unidirectional light emitters, such as DFB lasers; however, an omni-directional light emitter, such as an LED, requires a two dimensional (2D) grating to out-couple light propagating in any direction. Solar cells would also require 2D gratings to better in-couple light.

The coupling strength of the 1D or 2D periodic structures, which describes the efficiency of the structures to diffract light, is directly related to the index of refraction contrast between the grating layer and the semiconductor material. Therefore, the diffraction strength of embedded gratings would be higher for gratings made with void-gaps or air-gaps as compared to dielectric materials, such as SiO₂ or Si₃N₄, which are commonly used in LEO. Also, to increase the diffraction strength on optoelectronic devices, such as LEDs or lasers, it is desirable to grow the thinnest layer possible on top of the grating, which guarantees a higher interaction with electromagnetic guided modes created in the active region (which are commonly located over the embedded grating) [13]. For any device, it is also desirable to have reduced thicknesses, which translate into reduced growth times, i.e. diminished costs.

Thus, there is a need in the art for optimization of diffracting gratings for optoelectronic devices.

### SUMMARY OF THE INVENTION

To overcome the limitations in the prior art described above, and to overcome other limitations that will become apparent upon reading and understanding the present specification, the present invention discloses an optoelectronic structure comprised of nitride-based semiconductors having growth-embedded void-gap gratings or photonic crystals in one or two dimensions, which are optimized to yield high diffraction efficiency and planar epitaxial growth. The optimal dimensions of the growth-embedded void-gap gratings or photonic crystals to LEDs are calculated by numerical simulation using scattering matrix formalism. The present invention is applicable to any semiconductor device, as well as optoelectronic devices such as LEDs, LDs and solar cells.

### BRIEF DESCRIPTION OF THE DRAWINGS

Referring now to the drawings in which like reference numbers represent corresponding parts throughout:

FIGS. 1(a) and 1(b) are schematics of the lateral overgrowth technique, wherein FIG. 1(a) shows the dielectric stripes deposited over the semiconductor surface; and FIG. 1(b) shows the semiconductor after regrowth over the dielectric stripes.

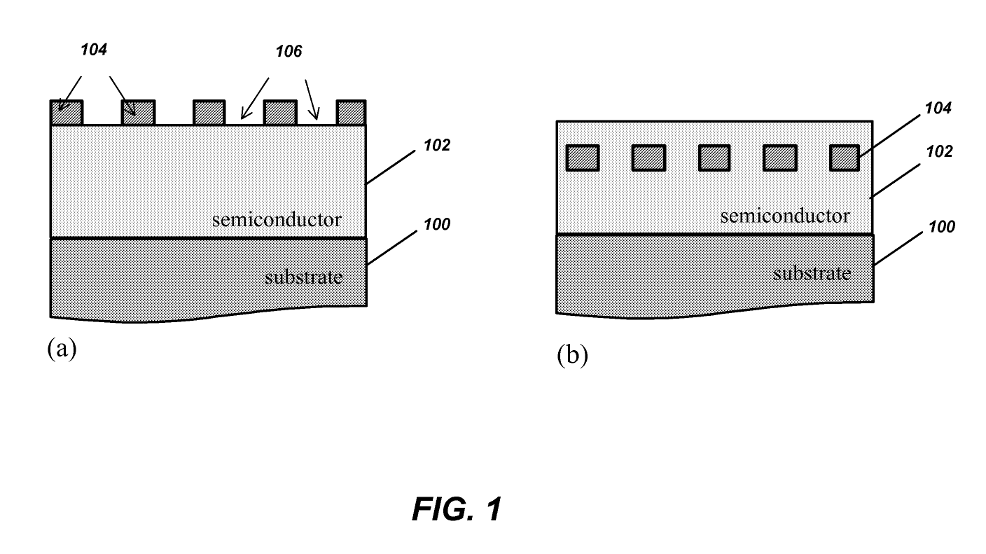

FIG. 2(a) is a schematic of the cross-section of a GaN-based surface PhC LED with the profile of a low and high order optical mode; and FIG. 2(b) shows the numerical simulation of the PhC extraction length for all the modes guided in the GaN slab versus the PhC depth.

FIG. 3(a) is a schematic of the cross-section of an embedded PhC LED; and FIG. 3(b) is a top view of the 2D-PhCs.

FIG. 4(a) is a plot of the calculated extraction length of the embedded PhC versus the index of refraction of the PhC material, and FIG. 4(b) is the calculation of the embedded PhC extraction length versus cap-layer thickness and PhC depth for LEDs.

FIG. 5(a) is a schematic of an LED with embedded void-gaps used to separate guided modes from optically absorbing layers, such as the bottom Ag metal commonly used as a reflector and as a current injecting electrode; FIG. 5(b) is a graph of the simulated absorption length due to the metal versus the depth of the embedded photonic crystals for all the guided modes in the structure; FIG. 5(c) is a graph of the simulated extinction length of the PhC versus the depth of the embedded photonic crystals; and FIG. 5(d) is a schematic of a double embedded PhC used to guide optical modes in the structure.

FIGS. 6(a)-6(d) comprise schematics of the process technique for the embedded air-gap features, wherein FIG. 6(a) shows a first step: pattern the semiconductor using an etching mask; FIG. 6(b) shows a second step: growth evolution during regrowth where the gaps get closed naturally due to different growth rates of the crystallographic facets, which reduces the growth rate inside the holes; FIG. 6(c) shows another possible mechanism during the growth over the patterned semiconductor, where damaged etched sidewalls block the semiconductor regrowth inside the gaps; and FIG. 6(d) shows the structure of the air-gaps (void-gaps) after coalescence of the overgrown layer.

FIGS. 7(a)-7(c) comprise schematics of a different fabrication process for embedded void-gap PhCs, wherein FIG. 7(a) shows a first step: etch the semiconductor using an etching mask; FIG. 7(b) shows a second step: compound material formation on the holes' sidewalls formed with a reactive gas plasma; and FIG. 7(c) shows a third step: semiconductor re-growth until coalescence is obtained, resulting in the air-gap (void-gap) structure.

FIG. 8(a) is a scanning electron microscope (SEM) image of the Si hard mask used to pattern the 2D PhC by nano-imprint lithography (NIL); FIG. 8(b) is an atomic force microscope (AFM) image prior to growth of the technique applied to GaN; FIG. 8(c) is a SEM image of the top; and FIG. 8(d) is a SEM image of a cross-section of the GaN after re-growth of GaN using the present invention.

FIG. 9(a) is a SEM image of another sample grown by the present invention revealing the feasibility of other configurations of embedded 2D void-gap structures, as applied to GaN, which includes a 300 nm-thick coalesced GaN over 300 nm-deep air-gaps; FIG. 9(b) is a SEM image of an LED structure with embedded 2D void-gap PhCs; and FIG. 9(c) is a photograph an embedded 2D void-gap PhC LED under electric injection. Notice the star-like emission in FIG. 9(c) in the ΓM (Gamma M) direction, which is one of the high-symmetry directions of the PhCs, wherein the ΓM (Gamma M) directions are conventions for the crystallographic direction ΓM from point Γ to point M in the reciprocal space.

FIG. 10(a) is a SEM image of the cross-section of a GaN-based optoelectronic device with embedded PhCs tested under illumination; and FIG. 10(b) is a plot of the external quantum efficiency (EQE) of the device with and without embedded PhCs, showing a 80% improvement in the photocurrent generated in the InGaN layer around 400 nm.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses a highly efficient optoelectronic structure based on growth of embedded PhCs on a semiconductor slab. The PhCs are gratings having void-gaps, air-gaps, or material voids, which results in a very high index contrast with other adjacent material layers and, consequently, a very high PhC diffraction strength. In one embodiment, a layer above the embedded void-gap PhCs is thin enough to provide a very high interaction between the electromagnetic guided modes in the semiconductor and the PhCs. Since the gaps within the PhCs are voids, the diffraction strength of the grating slab is the highest possible. The present invention also discloses the trends for optimal structures, such as LEDs, containing embedded void-gap features. While the present invention is applicable for any semiconductor, a simple, manufacturable and planar epitaxial growth method to produce embedded voids on nitride-based semiconductors is disclosed.

Technical Description

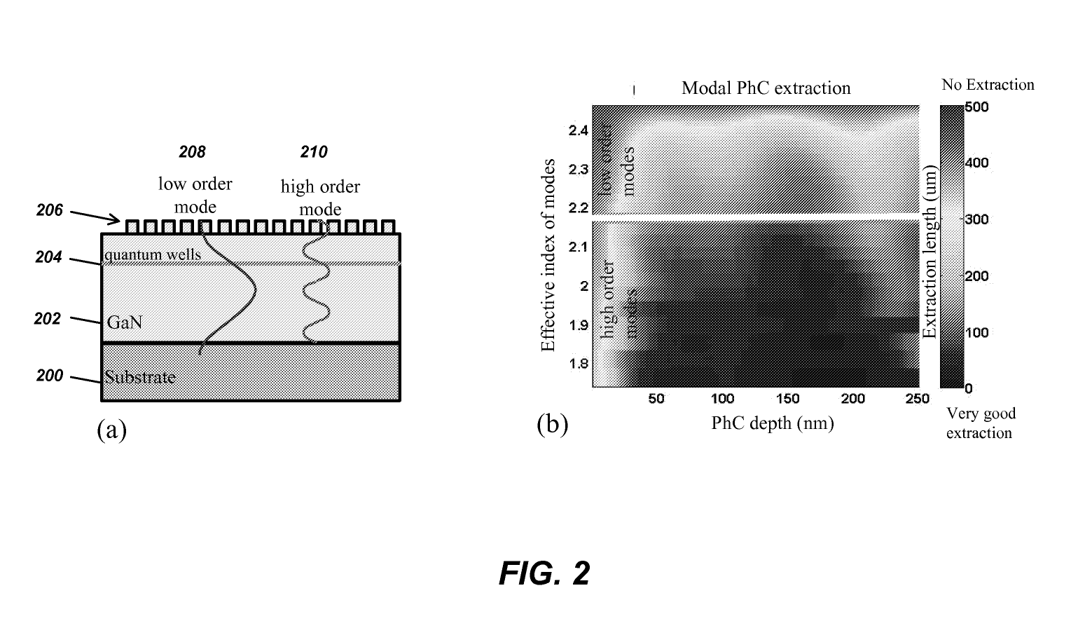

The enhancement of light extraction in LEDs by surface PhCs [7,8] and lasing action due to surface gratings in DFBs [9,10] have been successfully demonstrated in the literature. The limitation of surface PhCs is the poor interaction between guided modes and the surface PhCs [13,14], as shown in FIG. 2(a), which is a schematic of the cross-section of a GaN-based LED, including a substrate 200, GaN layer 202, active layer including quantum wells (QWs) 204, and surface PhC 206, showing the profiles of a low order optical mode 208 and a high order optical mode 210.

FIG. 2(b) illustrates a numerical simulation of the PhC extraction length for all the modes guided in the GaN slab versus the PhC depth. Specifically, FIG. 2(b) is a graph of the calculation based on the scattering matrix formalism [15] of the PhC extraction length for all the electromagnetic modes guided in the semiconductor slab containing the PhC. As noted in FIG. 2(a), the modes are divided in two different categories: low order and high order modes. The low order modes, each of them usually carrying a great fraction of the emitted light, have a poor overlap with the surface PhC, which results in a low extraction efficiency (or high extraction length), as shown in FIG. 2(b). The high order modes interact much better with the surface PhCs than the low order modes; however, the amount of light that each of them carries is smaller due to their lower overlap with the light emitting region (for example, quantum wells in LEDs).

Low order modes carry almost 40% of the guided energy; hence, their optimal diffraction is required to increase the overall efficiency of optoelectronic devices which, among other solutions, can be obtained by placing the grating inside the semiconductor structure (i.e., embedded PhCs).

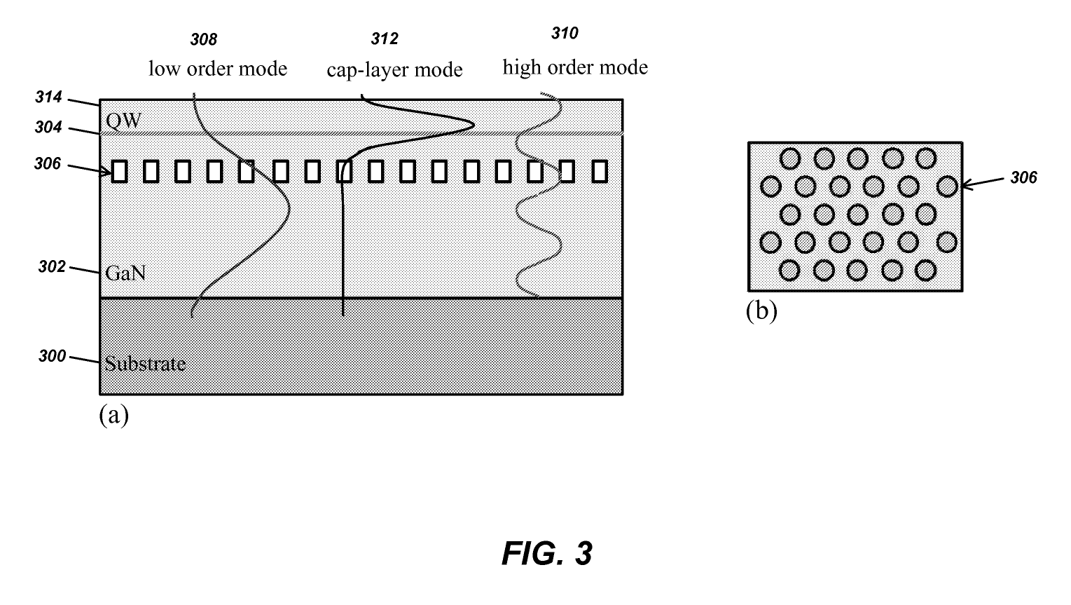

The present invention discloses a highly efficient optoelectronic device based on embedded void-gap PhCs, as shown in FIG. 3(a), which is a schematic of the cross-section of a GaN-based LED, including a substrate 300, GaN layer 302, active layer including quantum wells (QWs) 304, and embedded void-gap PhCs 306, showing the profiles of a low order optical mode 308, a high order optical mode 310, and a cap-layer mode (CLM) 312. The profile of the low and high order modes 308, 310 in FIG. 3(a) indicate their higher overlap with the embedded PhCs 306 as compared to surface PhCs 206 as shown in FIG. 2(a). The lower average index of refraction of the PhC layer 306 as compared to the GaN layer 302 causes the confinement of some low order modes, called cap-layer modes 312, on the top-most layer 314 of the structure (also called a cap-layer). The active layer (i.e., light emitting layer) is also located in the cap-layer 314; hence, it overlaps very well with the cap-layer mode 312. Therefore, the cap-layer mode 312 is very well excited by the active layer 304.

The PhCs can be arranged periodically or randomly, in one or two dimensions. While the application of embedded PhCs in one dimension (embedded 1D-PhC) is well adapted for lasers, its uni-directional diffraction can be disadvantageous for omni-directional applications, such as in LEDs or solar cells. In this case, embedded 2D-PhCs are required. A top view of the 2D PhCs 306 in FIG. 3(a) is depicted in FIG. 3(b).

The diffraction strength of the PhCs is directly related to its index of refraction (n) contrast with surrounding materials. Generally, dielectrics such as SiO₂ (n ˜1.5) or Si₃N₄ (n˜2) are used in the PhC layer to produce the modulation of the index of refraction. For GaN-based semiconductors (index of refraction: n ˜2.45), the index mismatch given by SiO₂ or Si₃N₄ gratings is not large and could be significantly enhanced by using void-gap PhCs, where the index of refraction in the void is n=1.

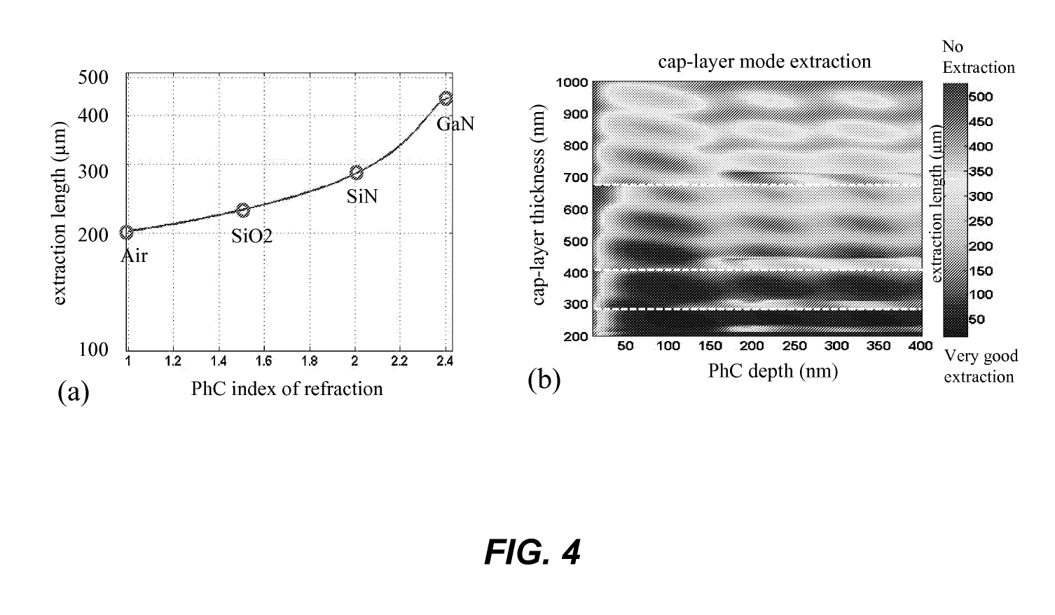

FIG. 4(a) is a graph of a numerical simulation [13] based on the scattering matrix formalism [15] of the variation of the PhC extraction length in LEDs versus the refractive index of the PhC material. While the values of extraction length are for a specific guided mode and structure, the trend can be generally applied. Because of the larger contrast in the index of refraction, the diffraction strength of the PhC is higher for a void-gap (in FIG. 4(a), “air” represents a void, since both the same index of refraction, namely n=1).

The diffraction of guided modes can be optimized by judiciously choosing the depth of the grating and the thickness of the cap-layer above the grating, as shown in the graph of FIG. 4(b), by the calculation of the extraction length of a GaN-based embedded void-gap PhC versus the top layer thickness and the PhC depth.

This numerical simulation was made for the electromagnetic mode guided in the top layer, i.e., the cap-layer mode. The cap-layer mode is the mode most excited by the quantum wells in such a structure. Additionally, all the other guided modes extend over the entire GaN layer and overlap well with the embedded PhCs; therefore, these modes are better extracted by the PhCs than the cap-layer mode. Hence, the optimization of the embedded PhC structure, considering just the diffraction of the cap-layer mode, is justified. The calculation in FIG. 4(b) shows that the PhC extraction length of the cap-layer mode reduces, or equivalently the diffraction efficiency increases, for a thin cap layer and a shallow PhC (˜100 nm).

For useful diffraction effects in optoelectronic devices, the PhC period is on the order of the wavelength of the light emitted by this device. For nitride based devices, the PhC period is close to 230 nm for so-called second order diffraction. This has implications for the epitaxial growth of the embedded PhC, which, as described in more detail below, is much different from the well-established growth techniques (such as LEO) that produce embedded gratings.

The same way that embedded PhCs confine an optical guided mode in the top-most layer (i.e., cap-layer) of the structure, as shown in FIG. 3(a), it can also be used to guide electromagnetic modes inside the structure. The lower average index of refraction of the embedded PhC layer, compared to the semiconductor materials in which it is embedded, can confine modes in a specific region of the semiconductor. Thus, a structure with more layers of embedded PhCs can be used to guide optical modes in a specific region inside the structure, for example, where the light emitting or absorbing species (or quantum wells) are located, and could be applied to lasers and to solar cells. The advantage is that there is no limitation on the thickness of the embedded void-gap PhCs, as well as no optical absorption; thus, it can confine optical lasing modes very well. The optical modes in lasers are usually confined to the active layers by cladding layers, which are usually grown by epitaxy in the laser structure. In some semiconductors, such as nitrides, the lattice mismatch between the laser active region and the cladding layer leads to cracking for thicknesses above a critical limit; hence, the thickness of the cladding layer is limited to this critical value, which can compromise the optical mode confinement. In addition, there is a much better confinement with void-gap layers, due to the much larger index difference between the active layers and the PhC void-gap layer acting as a confinement layer.

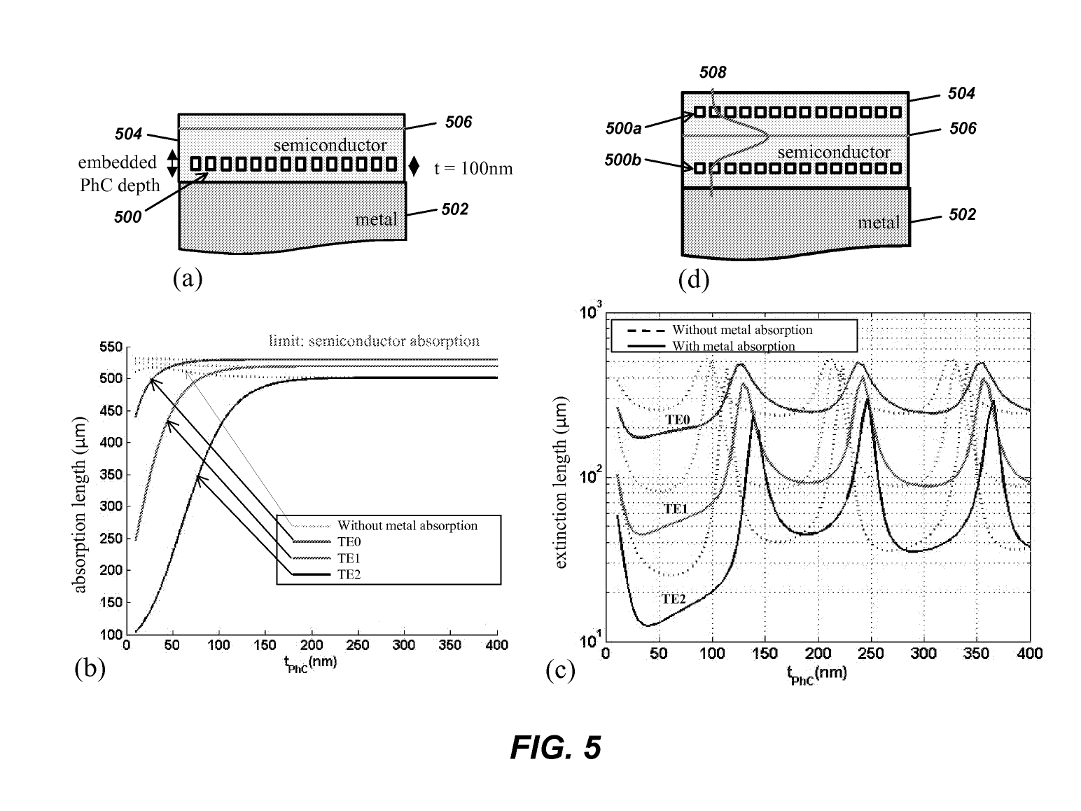

The confinement property of embedded void-gap PhCs can also be used to spatially separate the optical modes from optically absorbing layers, such as metals or doped regions. FIG. 5(a) is a schematic of an LED with embedded void-gaps 500 used to separate guided modes from optically absorbing layers, such as the bottom Ag metal layer 502 commonly used as a reflector and as a current injecting electrode, where the embedded PhCs 500 are placed close (e.g., an embedded PhC depth of approximately 100 nm) to the interface between the semiconductor 504 and the bottom Ag metal layer 502, i.e., between an active layer 506 and the metal layer 502.

FIG. 5(b) is a plot that shows the simulated absorption length of the metal as a function of the depth of the embedded PhCs, wherein the solid lines correspond respectively to the modes TE0, TE1 and TE2 of the structure and the dotted lines correspond to the simulated structure without taking into consideration the metal absorption, just the GaN absorption length, considered here to be ˜500 μm (this value gives an upper limit to the absorption which is useful for the numerical simulations). It is clearly seen that the absorption length increases with the embedded PhC depth (which is equivalent to a reduction on the modal absorption by the metal layer). For a PhC depth higher than 100-200 nm, the absorption length reaches the theoretical limit of the GaN absorption, which corresponds to the complete elimination of absorption from the metal.

FIG. 5(c) is a graph that shows the simulation of the PhC extinction length (extraction plus absorption) versus the PhC depth for the same three different modes simulated in FIG. 5(b) (indicated by the solid lines) in a similar 600 nm-thick structure. The dotted lines again correspond to the structure without metal absorption and therefore the extinction length in this case corresponds mainly to the PhC extraction length. The difference between the solid and dotted lines corresponds to the absorption from the metal, which clearly tends to zero as the PhC depth is increased. All the valleys in the extinction length curve correspond to PhC depths where the PhC extraction is the highest (short extinction length), which are the desired regions for light extraction enhancement by the embedded PhC in LEDs. Alternatively, all the peaks in this extinction length curve correspond to PhC depths at which the light extraction is very inefficient (very long extinction lengths). Therefore, this result shows that the embedded PhCs can be used for light extraction or light confinement depending on the PhC depth. Hence, the embedded PhCs can indeed be used as confining layers as long as the PhC depth is such that the PhC extraction is zero (peak values).

FIG. 5(d) is a schematic of a structure with a double embedded PhC 500a, 500b used to guide optical modes 508 in the structure, wherein the depth of the embedded PhCs 500a, 500b (i.e., the distance from the interface between the semiconductor layer 504 and metal layer 502) is chosen to result in a negligible PhC extraction and therefore this structure could be applied to guide light with a strong optical confinement in the active region, as required for best operation of lasers or solar cells.

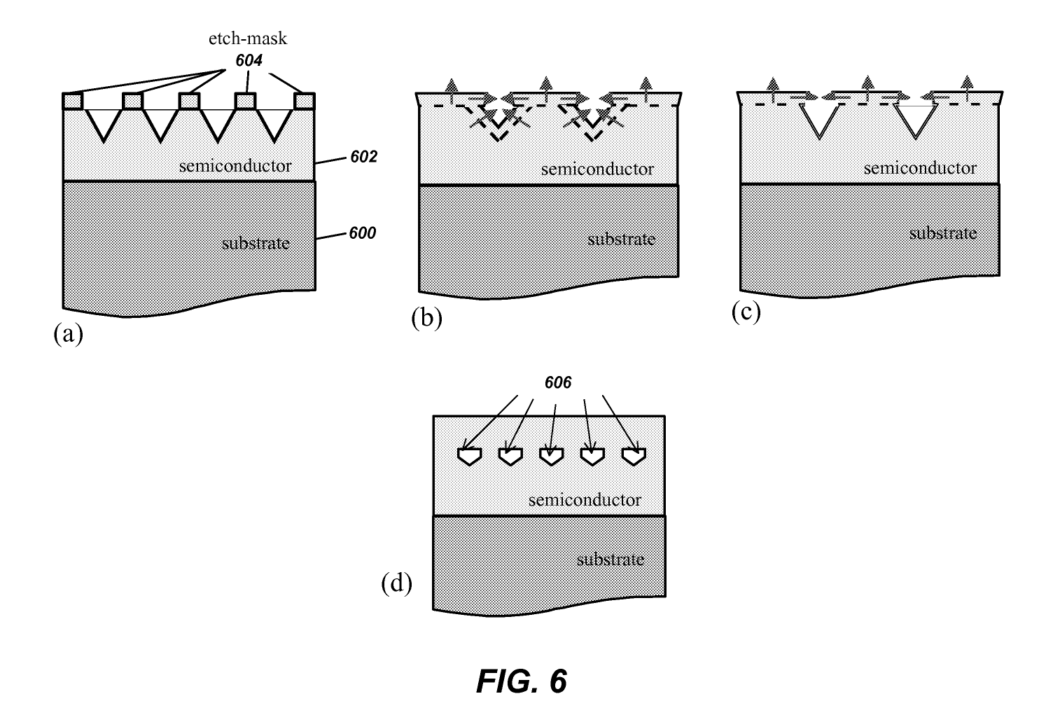

A first method to obtain optoelectronic devices with growth-embedded void-gap PhC features according to the present invention is depicted in FIGS. 6(a)-6(d). Initially, as shown in FIG. 6(a), a substrate 600 is provided, and a semiconductor layer 602 is deposited thereon. Then, a layer of etch-mask 604 is deposited over the surface of the semiconductor layer 602, wherein the etch-mask 604 is subsequently patterned with the features of interest. Several techniques can be used to pattern the etch-mask 604, such as electron-beam lithography or nano-imprint lithography (NIL) [7,14]. The pattern is then transferred to the semiconductor layer 602. In the specific case of GaN, the pattern transfer is made by dry etching via reactive ion etching (RIE) or inductive coupled plasma etching (ICP). The etch-mask 604 is subsequently removed, leaving the un-etched surface of the semiconductor layer 602 completely clear for re-growth.

During re-growth, several effects can be used to obtain voids:

1. The growth occurs over the entire surface of the semiconductor layer 602 including the etched holes with a resulting closure of partially filled holes, as shown in FIG. 6(b). This scenario is made possible by the different growth rates of the horizontal surface and the hole surfaces, as shown by the arrows in FIG. 6(b), and results in embedded void-gaps (air-gaps) 606, as shown in FIG. 6(d), with approximately the same volume as before re-growth. Also, depending on the exposed facet inside the holes, the growth rate of this facet can be different from the un-etched one, which contributes to embedded voids in the semiconductor layer 602.

2. During the semiconductor layer 602 etch step, surface damage on the sidewalls of the holes due to etching can prevent or slow growth, as shown by the lack of arrows for the sidewalls in FIG. 6(c), which would also result in embedded air-gaps.

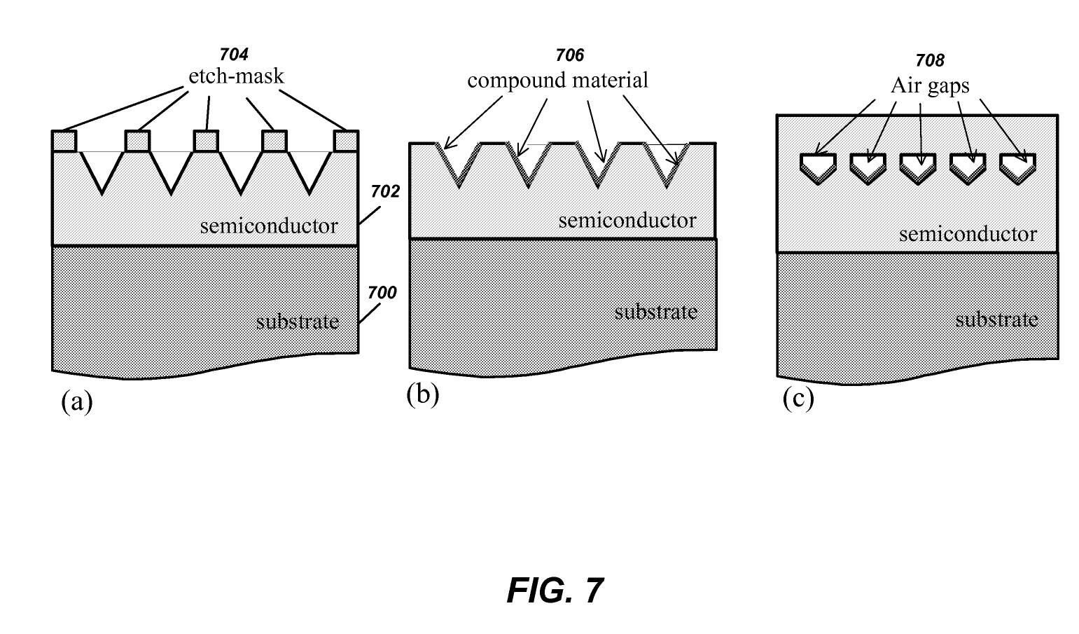

3. In the specific case of dry-etching of the holes, reactive gas plasma can be induced in-situ, for example, of O₂, CF₄ or SF₆, to form a layer of a compound material, such as oxide or fluoride, in the sidewalls of the holes. This process is depicted in FIGS. 7(a), 7(b), and 7(c). Initially, as shown in FIG. 7(a), a substrate 700 is provided, and a semiconductor layer 702 is deposited thereon. Then, a layer of etch-mask 704 is deposited over the surface of the semiconductor layer 702. During the etch, the compound material 706 is formed in the sidewalls of the holes. After the etch-mask 704 removal, the surface of the semiconductor layer 702 is available for re-growth, while the sidewalls of the holes are covered by a growth-blocking mask comprised of the compound material 706 formed in-situ during the etch step. Thus, the re-growth step embeds air-gap features 708 with approximately the same volume as the holes had before the growth.

GaN-based structures with embedded 2D photonic crystals have been previously reported, wherein they were achieved through a process where a dielectric layer is used to block growth inside the holes [16]. The advantage of the present invention is clear: it is a simpler process for the formation of embedded voids, without requiring depositing a dielectric growth-blocking layer, thus avoiding a deposition step. The scattering efficiency of the PhC is higher due to the larger index contrast between matrix and air.

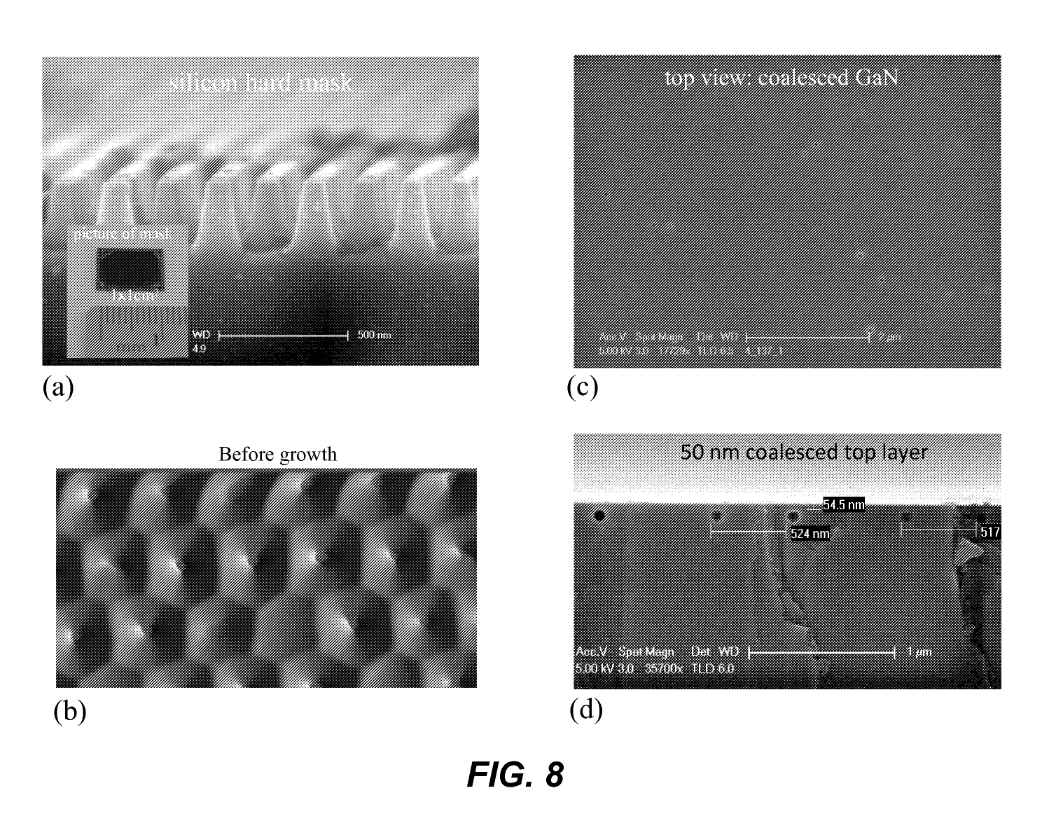

Applications of embedded void structures formed through the process disclosed in the present invention were successfully observed for GaN. First, an n-doped GaN sample was patterned by NIL using a Si hard mask with a 2D triangular lattice, as shown in FIG. 8(a). The sample was etched by RIE using 10 sccm of Cl₂ at 5 m Torr and 200 W, which resulted in “v-shaped” holes, as shown in FIG. 8(b). Then, GaN was regrown by metal-organic chemical vapor deposition (MOCVD) at 85 Torr, 1165° C., 10 sccm of Trimethylgallium (TMG) and 6 slm of ammonia (NH3) for 2440 seconds (s). A 50 nm-thick GaN layer was coalesced over the void-gaps, as shown in FIGS. 8(c) and 8(d), even though no dielectric was used to block the GaN growth on the holes.

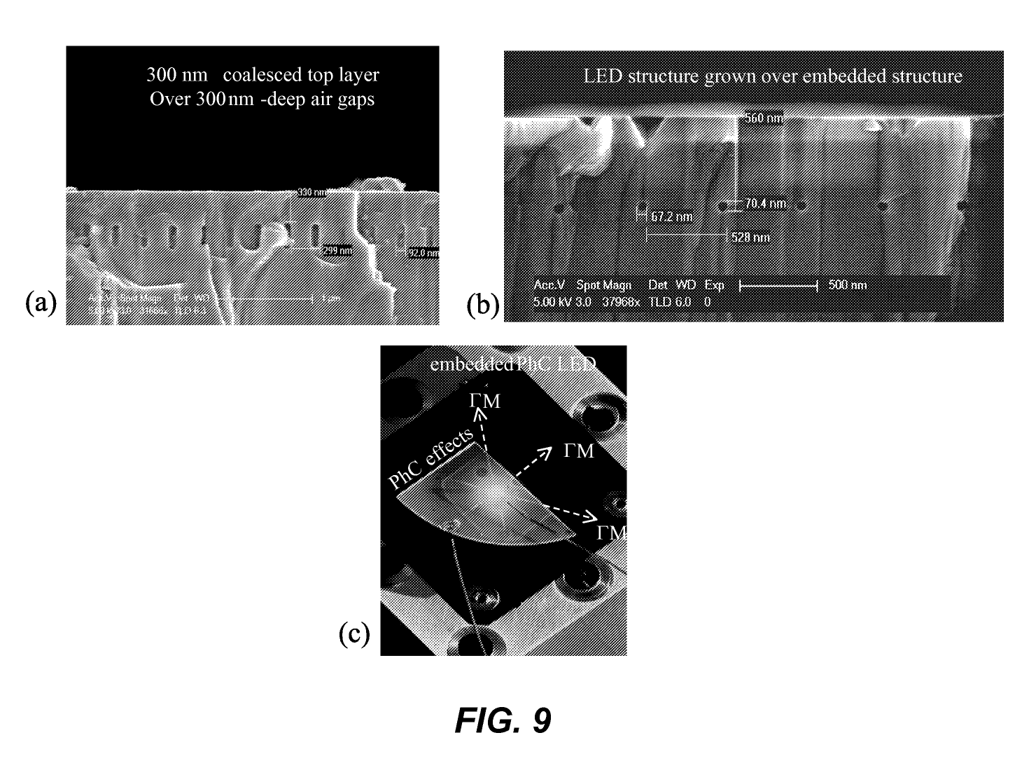

Other configurations for the embedded void structures were also achieved for GaN. FIG. 9(a) is a SEM image of an optoelectronic device where 300 nm-deep void-gaps in a 2D triangular lattice were embedded under a 300 nm-thick coalesced GaN layer, and FIG. 9(b) is a SEM image of an optoelectronic device where a 560 nm-thick LED is grown over 100 nm-deep air holes PhC with a 2D triangular lattice. The effect of the embedded void-gap PhCs on the optoelectronic device of FIG. 9(b) are clearly seen in the photograph of FIG. 9(c). In addition to the normal LED light emission, there is an extra amount of light coming out of the device in a star-like shape, as shown in FIG. 9(c), which corresponds to guided modes being extracted along the ΓM or ΓM directions of the 2D PhCs. Close to unity light extraction efficiency was obtained by embedded PhCs (94%), which shows the enormous potential of the present invention in improving light extraction in LEDs (see [18] and [19] for more details).

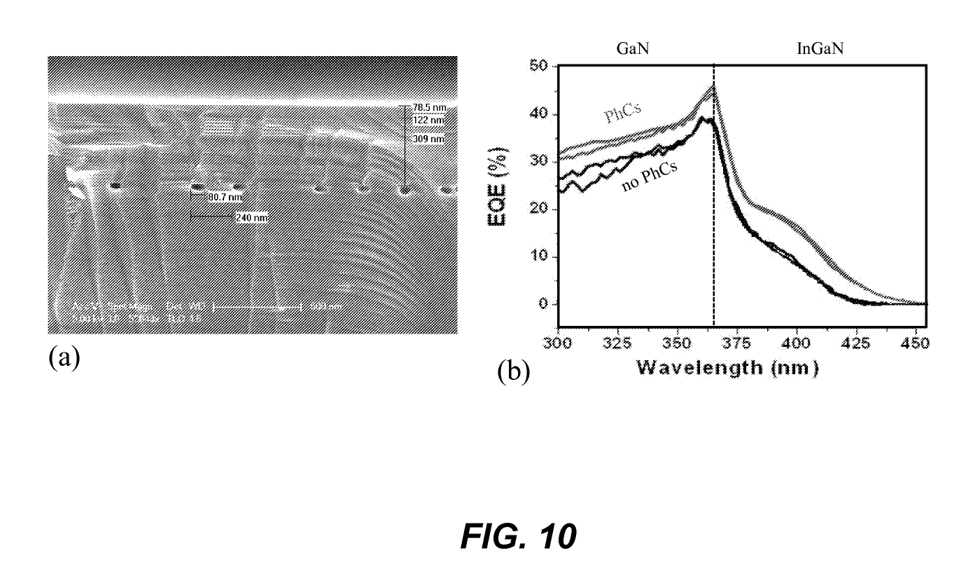

The technique of void-gap embedded PhCs can also be applied to solar cells. It is a well-known problem in thin film solar cells that one has to compromise between good light absorption which requires active absorbing layers thick enough (more than the absorption length) and high photocarrier collection efficiency which requires absorbing layers thinner than the diffusion length. PhCs allow a better absorption for a given thickness by redistributing incoming light into guided optical modes which have a long interaction length with the active layer [17]. The embedded photonic crystal of the present invention, for example, as shown in FIG. 10(a), indeed leads to increased absorption, as revealed by the increase in photocurrent of such devices, as shown in FIG. 10(b).

The fabrication technique according to the presented invention can be repeated one or more times to obtain more layers of embedded void-gap photonic crystals in the structure. Ultimately, several layers of 2D PhCs can be piled up, where the two adjacent layers are judiciously shifted to form a three dimensional embedded void-gap PhC.

### REFERENCES

The following references are incorporated by reference herein:
[1] Yoshiki Kato, Shota Kitamura, Kazumasa Hiramatsu, and Nobuhiko Sawaki. Selective growth of wurtzite GaN and AlₓGa₁₋ₓN on GaN/Sapphire substrates by metalorganic vapor phase epitaxy. Journal of Crystal Growth, 144(3-4):133-140, December 1994.
[2] Ok-Hyun Nam, Michael D. Bremser, Tsvetanka S. Zheleva, and Robert F. Davis. Lateral epitaxy of low defect density GaN layers via organometallic vapor phase epitaxy. Applied Physics Letters, 71(18):2638-2640, 1997.
[3] Akira Usui, Haruo Sunakawa, Akira Sakai, and A. Atsushi Yamaguchi. Thick GaN epitaxial growth with low dislocation density by hydride vapor phase epitaxy. Japanese Journal of Applied Physics, 36(Part 2, No. 7B):L899-L902, 1997.
[4] Pierre Gibart. Metal organic vapour phase epitaxy of GaN and lateral overgrowth. Reports on Progress in Physics, (5):667, 2004.
[5] B. Beaumont, V. Bousquet, P. Venngus, M. Vaille, A. Bouill, P. Gibart, S. Dassonneville, A. Amokrane, and B. Sieber. A two-step method for epitaxial lateral overgrowth of GaN. physica status solidi (a), 176(1):567-571, 1999.
[6] B. Beaumont, Ph. Venngus, and P. Gibart. Epitaxial lateral overgrowth of GaN. physica status solidi (b), 227(1):1-43, 2001.
[7] J. J. Wierer, M. R. Krames, J. E. Epler, N. F. Gardner, M. G. Craford, J. R. Wendt, J. A. Simmons, and M. M. Sigalas. InGaN/GaN quantum-well heterostructure light-emitting diodes employing photonic crystal structures. Applied Physics Letters, 84(19):3885-3887, 2004.
[8] A. David, C. Meier, R. Sharma, F. S. Diana, S. P. DenBaars, E. Hu, S, Nakamura, C. Weisbuch, and H. Benisty. Photonic bands in two-dimensionally patterned multimode GaN waveguides for light extraction. Applied Physics Letters, 87(10):101107, 2005.
[9] R. Hofmann, H.-P. Gauggel, U. A. Griesinger, H. Grabeldinger, F. Adler, P. Ernst, H. Bolay, V. Harle, F. Scholz, H. Schweizer, and M. H. Pilkuhn. Realization of optically pumped second-order gain distributed-feedback lasers. Appl. Phys. Lett., 69(14):2068-2070, September 1996.
[10] Daniel Hofstetter, Robert L. Thornton, Linda T. Romano, David P. Bour, Michael Kneissl, and Rose M. Donaldson. Room-temperature pulsed operation of an electrically injected InGaN/GaN multi-quantum well distributed feedback laser. Applied Physics Letters, 73(15):2158-2160, 1998.
[11] A. C. Abare, M. Hansen, J. S. Speck, S. P. DenBaars, and L. A. Coldren. Electrically pumped distributed feedback nitride lasers employing embedded dielectric gratings. Electronics Letters, 35(18):1559-1560, 1999.
[12] Aurelien David, Brendan Moran, Kelly McGroddy, Elison Matioli, Evelyn L. Hu, Steven P. DenBaars, Shuji Nakamura, and Claude Weisbuch. Gan/InGaN light emitting diodes with embedded photonic crystal obtained by lateral epitaxial overgrowth. Applied Physics Letters, 92(11):113514, 2008.
[13] Elison Matioli, Michael Iza, Yong-Seok Choi, Feng Wu, Stacia Keller, Hisashi Masui, Evelyn Hu, James Speck, and Claude Weisbuch. GaN-based embedded 2D photonic crystal LEDs: Numerical optimization and device characterization. Phys. Status Solidi C, 1-5, 2009.
[14] David, A.; Fujii, T.; Sharma, R.; McGroddy, K.; Nakamura, S.; DenBaars, S. P.; Hu, E. L.; Weisbuch, C. & Benisty, H. Photonic-crystal GaN light-emitting diodes with tailored guided modes distribution, Applied Physics Letters, AlP, 2006, 88, 061124.
[15] S. G. Tikhodeev, A. L. Yablonskii, E. A. Muljarov, N. A. Gippius, and T. Ishihara, Physical Review B, 66, 045102 (2002).
[16] Hideki Matsubara, Susumu Yoshimoto, Hirohisa Saito, Yue Jianglin, Yoshinori Tanaka, and Susumu Noda. GaN photonic-crystal surface-emitting laser at blue-violet wavelengths. Science, 319:445, (2008).
[17] Peter Bermel, Chiyan Luo, Lirong Zeng, Lionel C. Kimerling, and John D. Joannopoulos, Improving thin-film crystalline silicon solar cell efficiencies with photonic crystals, Optics Expr. 15: 16986 (2007).
[18] Elison Matioli, Stacia Keller, Feng Wu, Yong-Seok Choi, Evelyn Hu, James Speck, and Claude Weisbuch, “Growth of embedded photonic crystals for GaN-based optoelectronic devices,” Journal of Applied Physics 106, 024309 (2009). This publication is attached as Appendix A to parent U.S. Provisional Application Ser. No. 61/367,239 cross-referenced above.
[19] Elison Matioli, Elizabeth Rangel, Micheal Iza, Blaise Fleury, Nathan Pfaff, James Speck, Evelyn Hu, and Claude Weisbuch, “High extraction efficiency light-emitting diodes based on embedded air-gap photonic-crystals,” Applied Physics Letters 96, 031108 (2010). This publication is attached as Appendix B to parent U.S. Provisional Application Ser. No. 61/367,239 cross-referenced above.

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
(a) an active layer that emits or absorbs light; and
(b) one or more layers, adjacent the active layer, comprised of growth-embedded void-gap gratings for increasing the light's interactions in the device.

2. The device of claim 1, wherein the light is extracted from or absorbed in the device by diffraction, reflection, refraction, or scattering caused by the growth-embedded void-gap gratings.

3. The device of claim 1, wherein the growth-embedded void-gap gratings comprise photonic crystals.

4. The device of claim 3, wherein the photonic crystals are one-dimensional or two-dimensional photonic crystals.

5. The device of claim 4, wherein two or more layers of the one-dimensional or two-dimensional photonic crystals form a three-dimensional photonic crystal.

6. The device of claim 1, wherein the growth-embedded void-gap gratings guide the light inside the device by means of a lower average index of refraction as compared to adjacent layers.

7. The device of claim 1, wherein the layers are comprised of III-nitride semiconductor.

8. The device of claim 1, wherein the device is a light-emitting diode (LED), a laser diode (LD), or a solar cell.

9. A method for fabricating an optoelectronic device, comprising:
(a) forming an active layer that emits or absorbs light; and
(b) forming one or more layers, adjacent the active layer, comprised of growth-embedded void-gap gratings for increasing the light's interactions in the device.

10. The method of claim 9, wherein the light is extracted from or absorbed in the device by diffraction, reflection, refraction, or scattering by the growth-embedded void-gap gratings.

11. The method of claim 9, wherein the growth-embedded void-gap gratings comprise photonic crystals.

12. The method of claim 11, wherein the photonic crystals are one-dimensional or two-dimensional photonic crystals.

13. The method of claim 12, wherein two or more layers of the one-dimensional or two-dimensional photonic crystals form a three-dimensional photonic crystal.

14. The method of claim 9, wherein the growth-embedded void-gap gratings guide the light inside the device by means of a lower average index of refraction as compared to adjacent layers.

15. The method of claim 9, wherein the layers are comprised of III-nitride semiconductor.

16. The method of claim 9, wherein the device is a light-emitting diode (LED), a laser diode (LD), or a solar cell.
